(19) United States
(12) Patent Application Publication
(10) Pub. No.: US 2019/0323134 A1
(43) Pub. Date: Oct. 24, 2019

(54) PHOTOCATALYST ELECTRODE FOR OXYGEN GENERATION, PRODUCTION METHOD FOR SAME, AND MODULE

(71) Applicants: FUJIFILM Corporation, Tokyo (JP); Japan Technological Research Association of Artificial Photosynthetic Chemical Process, Tokyo (JP); THE UNIVERSITY OF TOKYO, Tokyo (JP)

(72) Inventors: Yusuke ASAKURA, Tokyo (JP); Kazunari DOMEN, Tokyo (JP); Taro YAMADA, Tokyo (JP); Hiroyuki KOBAYASHI, Tokyo (JP); Hiroshi NISHIYAMA, Tokyo (JP)

(73) Assignees: FUJIFILM Corporation, Tokyo (JP); Japan Technological Research Association of Artificial Photosynthetic Chemical Process, Tokyo (JP); THE UNIVERSITY OF TOKYO, Tokyo (JP)

(21) Appl. No.: 16/438,008

(22) Filed: Jun. 11, 2019

Related U.S. Application Data
(63) Continuation of application No. PCT/JP2017/044542, filed on Dec. 12, 2017.

(30) Foreign Application Priority Data
Dec. 12, 2016 (JP) 2016-240361

(51) Int. Cl. C25B 11/04; C25B 1/04; B01J 27/24; B01J 35/00; C23C 16/30

(52) U.S. Cl. CPC C25B 11/0426; C25B 1/04; C23C 16/303; B01J 35/004; B01J 27/24

(57) ABSTRACT

The present invention has an object to provide a photocatalyst electrode for oxygen generation having excellent photocurrent density, a production method for a photocatalyst electrode for oxygen generation and a module, and the photocatalyst electrode for oxygen generation of the present invention includes a current collector layer and a photocatalyst layer containing Ta₃N₅, wherein the photocatalyst electrode for oxygen generation has a charge separation promotion layer between the current collector layer and the photocatalyst layer.

### CROSS-REFERENCE TO RELATED APPLICATIONS

This application is a Continuation of PCT International Application No. PCT/JP2017/044542 filed on Dec. 12, 2017, which claims priority under 35 U.S.C. § 119(a) to Japanese Patent Application No. 2016-240361 filed on Dec. 12, 2016. The above application is hereby expressly incorporated by reference, in its entirety, into the present application.

### BACKGROUND OF THE INVENTION

### 1. Field of the Invention

The present invention relates to a photocatalyst electrode for oxygen generation, a production method for a photocatalyst electrode for oxygen generation and a module.

### 2. Description of the Related Art

From the viewpoints of carbon dioxide emission reduction and more use of clean energy, attention has been focused on techniques for producing hydrogen and oxygen by utilizing solar energy and decomposing water using a photocatalyst.

Water splitting methods using a photocatalyst can be broadly classified into two types. The first is a method of carrying out a water splitting reaction in a suspension using a powder photocatalyst, and the second is a method of performing a water splitting reaction using an electrode formed by depositing a photocatalyst on a conductive support (for example, a current collector layer, or the like), and a counter electrode.

Of such water splitting methods, the latter method of water splitting provides advantages such as the ability to separately recover hydrogen and oxygen. As a photocatalyst electrode for water splitting that is used in this type of water splitting method, a “photocatalyst electrode for water splitting, comprising: a photocatalyst layer; a current collector layer disposed on the photocatalyst layer and formed by a vapor deposition method” is disclosed, for example, in JP 2016-55279 A.

### SUMMARY OF THE INVENTION

In recent years, there has been a demand for more efficient progression of water splitting and for further improvements in the characteristics of photocatalyst electrodes.

Here, water splitting by a two-electrode water splitting module occurs where the splitting efficiency of the photocatalyst electrode for hydrogen generation matches the splitting efficiency of the photocatalyst electrode for oxygen generation. In general, since the performance of photocatalyst electrodes for oxygen generation is often poor, increasing the water splitting efficiency of the photocatalyst electrode for oxygen generation leads to increased performance as a module.

One method for improving the performance of photocatalyst electrodes for oxygen generation is to improve the photocurrent density.

The inventors of the present invention produced a photocatalyst electrode for oxygen generation using the photocatalyst described in the Examples section of JP 2016-55279 A, and discovered that there is room for improvement in photocurrent density.

Therefore, an object of the present invention is to provide a photocatalyst electrode for oxygen generation having excellent photocurrent density, and a module containing the photocatalyst electrode for oxygen generation.

As a result of conducting diligent research on the abovementioned problems, the present inventors discovered that when a photocatalyst layer containing Ta₃N₅ is used, excellent photocurrent density of a photocatalyst electrode for oxygen generation is achieved by disposing a charge separation promotion layer between the photocatalyst layer and the current collector layer, and thus completing the invention.

Namely, the present inventors discovered that the abovementioned problems can be solved by the following configuration.

[1]

A photocatalyst electrode for oxygen generation comprising a current collector layer and a photocatalyst layer containing Ta₃N₅,

wherein the photocatalyst electrode for oxygen generation has a charge separation promotion layer between the current collector layer and the photocatalyst layer,

the charge separation promotion layer comprises an inorganic material in which an upper end of a valence band of the charge separation promotion layer is at a deeper level than an upper end of a valence band of the photocatalyst layer, and a lower end of a conduction band of the charge separation promotion layer is at a deeper level than a lower end of a conduction band of the photocatalyst layer, and

the inorganic material is GaN.

[2]

The photocatalyst electrode for oxygen generation according to [1], wherein the inorganic material is a crystalline inorganic material.

[3]

The photocatalyst electrode for oxygen generation according to [2], wherein the inorganic material is crystalline GaN.

[4]

The photocatalyst electrode for oxygen generation according to [3], wherein a diffraction peak intensity of a (002) surface of the crystalline GaN measured by X-ray diffraction using CuKα radiation is greater than 1 when the diffraction peak intensity of the (002) surface of a GaN layer produced by method A is regarded as 1;

Method A: A GaN layer with a film thickness of 50 nm is formed on a sapphire substrate at 300° C. using plasma chemical vapor deposition method.

[5]

The photocatalyst electrode for oxygen generation according to [1], wherein the Ta₃N₅ is Ta₃N₅ doped with a material that widens the bandgap.

[6]

The photocatalyst electrode for oxygen generation according to [5], wherein the material that widens the bandgap is at least one element of Zr and Mg.

[7]

The photocatalyst electrode for oxygen generation according to [1], wherein the current collector layer comprises at least one layer containing Ta.

[8]

The photocatalyst electrode for oxygen generation according to [1], wherein the current collector layer comprises at least one layer containing Ti.

[9]

The photocatalyst electrode for oxygen generation according to [7], wherein the layer containing Ta is laminated in contact with the charge separation promotion layer.

[10]

The photocatalyst electrode for oxygen generation according to [9], wherein the current collector layer comprises at least one layer containing Ti; and

the layer containing Ti is laminated on a surface of the layer containing the Ta, the surface being of a side opposite the surface in contact with the charge separation promotion layer.

[11]

A module comprising the photocatalyst electrode for oxygen generation according to [1].

[12]

A method for producing a photocatalyst electrode for oxygen generation, the method comprising the steps of:

forming a photocatalyst layer containing Ta₃N₅ on a substrate;

forming a charge separation promotion layer on the photocatalyst layer;

forming a current collector layer on the charge separation promotion layer; and

peeling the substrate from the photocatalyst layer,

wherein the charge separation promotion layer comprises an inorganic material in which an upper end of a valence band of the charge separation promotion layer is at a deeper level than an upper end of a valence band of the photocatalyst layer, and a lower end of a conduction band of the charge separation promotion layer is at a deeper level than a lower end of a conduction band of the photocatalyst layer, and the inorganic material is GaN.

[13]

The method for producing a photocatalyst electrode for oxygen generation according to [12], wherein the inorganic material is a crystalline inorganic material.

[14]

The method for producing a photocatalyst electrode for oxygen generation according to [13], wherein the inorganic material is crystalline GaN.

[15]

The method for producing a photocatalyst electrode for oxygen generation according to [14], wherein a diffraction peak intensity of a (002) surface of the crystalline GaN measured by X-ray diffraction using CuKα radiation is greater than 1 when the diffraction peak intensity of the (002) surface of a GaN layer produced by method A is regarded as 1;

Method A: A GaN layer with a film thickness of 50 nm is formed on a sapphire substrate at 300° C. using plasma chemical vapor deposition.

[16]

The method for producing a photocatalyst electrode for oxygen generation according to [12], wherein the charge separation promotion layer is formed by a vapor phase film formation method.

[17]

The method for producing a photocatalyst electrode for oxygen generation according to [16], wherein the vapor phase film formation method is a chemical vapor deposition method or sputtering method.

[18]

The method for producing a photocatalyst electrode for oxygen generation according to [17], wherein the chemical vapor deposition method is a plasma chemical vapor deposition method.

[19]

The photocatalyst electrode for oxygen generation according to [2], wherein the Ta₃N₅ is Ta₃N₅ doped with a material that widens the bandgap.

[20]

The photocatalyst electrode for oxygen generation according to [3], wherein the Ta₃N₅ is Ta₃N₅ doped with a material that widens the bandgap.

As described below, according to the present invention, a photocatalyst electrode for oxygen generation having excellent photocurrent density and a module containing the photocatalyst electrode can be provided.

### BRIEF DESCRIPTION OF THE DRAWINGS

FIG. 1 is a cross-sectional view of an electrode, schematically illustrating one embodiment of a photocatalyst electrode for oxygen generation of the present invention.

FIG. 2 is a schematic cross-sectional view illustrating a portion of the process of the method for producing the photocatalyst electrode for oxygen generation of the present invention.

FIG. 3 is a schematic cross-sectional view illustrating a portion of the process of the method for producing the photocatalyst electrode for oxygen generation of the present invention.

FIG. 4 is a schematic cross-sectional view illustrating a portion of the process of the method for producing the photocatalyst electrode for oxygen generation of the present invention.

FIG. 5 is a schematic cross-sectional view illustrating a portion of the process of the method for producing the photocatalyst electrode for oxygen generation of the present invention.

### DESCRIPTION OF THE PREFERRED EMBODIMENTS

The photocatalyst electrode for oxygen generation (hereinafter referred to as “oxygen generating electrode”) and a module containing the same according to the present invention will be described below.

Note that numerical ranges expressed using “from . . . to . . . ” in the present specification indicate ranges that include the numerical values shown before and after “to” as the lower and upper limit values.

### Oxygen Generating Electrode

The oxygen generating electrode of the present invention is a photocatalyst electrode for generating oxygen, the electrode including a current collector layer and a photocatalyst layer containing Ta₃N₅, and having a charge separation promotion layer between the current collector layer and the photocatalyst layer. The oxygen generating electrode of the present invention is suitable for water splitting.

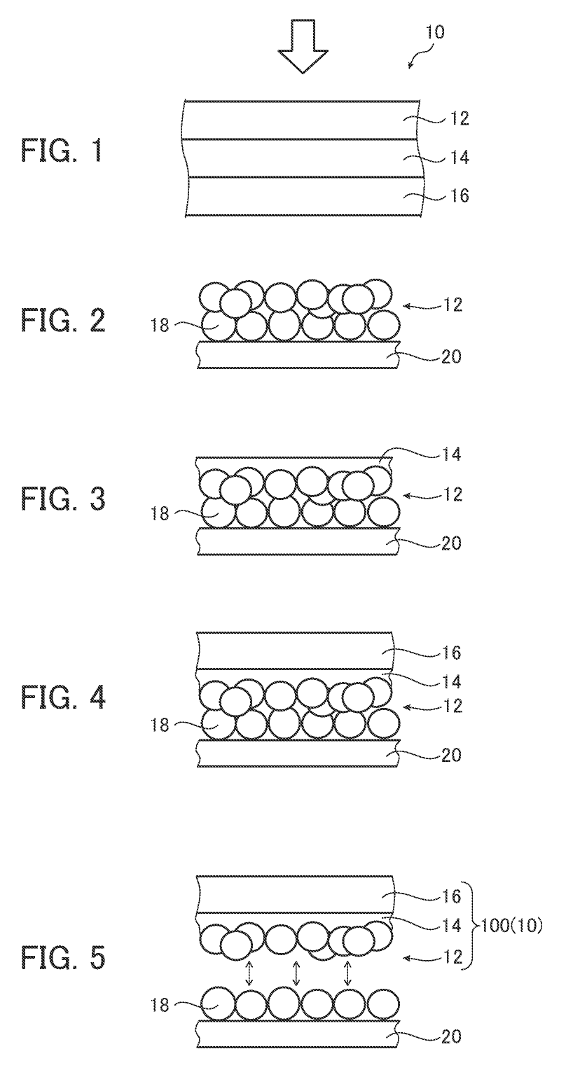

FIG. 1 is a cross-sectional view illustrating one embodiment of an oxygen generating electrode of the present invention. As illustrated in FIG. 1, an oxygen generating electrode 10 includes a photocatalyst layer 12 as a photocatalyst, a charge separation promotion layer 14, and a current collector layer 16. Typically, the oxygen generating electrode 10 is often irradiated with light from the direction of the white arrow outlined in black, and in this case, the surface of the photocatalyst layer 12 on the side opposite the charge separation promotion layer 14 is a light receiving surface.

By irradiating the oxygen generating electrode 10 with light, electrons and electron holes (holes) are produced in the photocatalyst layer 12. Electrons produced by the photocatalyst layer 12 pass through the charge separation promotion layer 14 and are transported to the current collector layer 16, recombine with holes generated by a counter electrode (a photocatalyst electrode for hydrogen generation) connected by wiring, and disappear. On the other hand, the holes produced in the photocatalyst layer 12 are transported to the surface of the photocatalyst layer 12 on the side opposite the charge separation promotion layer 14, and are used to generate oxygen through water splitting.

Ordinarily with the transport of electrons and holes generated in a photocatalyst layer, only the drift due to a concentration gradient of the generated carriers acts as a driving force, and therefore holes for which arrival to the surface of the photocatalyst layer of a side opposite the current collector layer is desired may move towards the current collector layer. Holes that cannot reach the surface of the photocatalyst layer of a side opposite the current collector layer will be deactivated by recombination in the photocatalyst layer, meaning that the quantum yield will become low. As a result, it is thought that the photocurrent density of the oxygen generating electrode will become low.

Here, the oxygen generating electrode 10 has the charge separation promotion layer 14 between the photocatalyst layer 12 and the current collector layer 16, thereby solving the problems described above. The charge separation promotion layer 14 functions to suppress recombination of the carriers in the photocatalyst layer 12, and specifically, for electrons and holes produced in the photocatalyst layer 12, the charge separation promotion layer 14 moves electrons to the current collector layer side, and moves the holes to a surface side of the photocatalyst layer 12 of the side opposite the current collector layer 16. In particular, the function described above is further exhibited by the charge separation promotion layer 14 including an inorganic material having the following properties. That is, in a case where the lower end of the conduction band and the upper end of the valence band of the inorganic material of the charge separation promotion layer 14 are in a low position in comparison to those of Ta₃N₅ constituting the photocatalyst layer 12, the electrons can pass through the charge separation promotion layer 14, but the holes cannot pass through the charge separation promotion layer 14. Therefore, recombination of carriers inside the photocatalyst layer 12 can be suppressed, and a driving force that transports the holes to the surface due to the concentration gradient of the generated carriers can be generated, and thus an effect of improving quantum yield can be obtained. It is presumed that as a result, the photocurrent density of the oxygen generating electrode 10 is further improved.

Each member constituting the oxygen generating electrode of the present invention will be described in detail below.

### Photocatalyst Layer

The photocatalyst layer contains Ta₃N₅. Ta₃N₅ is a visible light-responsive photocatalyst. Even amongst oxygen generating photocatalysts, Ta₃N₅ has excellent properties including exhibiting long wavelength responsiveness and improving the water splitting efficiency of the photocatalyst electrode.

The photocatalyst layer is disposed on one side of a charge separation promotion layer described below. The photocatalyst layer may be formed on at least a portion of one side of the charge separation promotion layer.

The Ta₃N₅ may be present in a form in which a plurality of Ta₃N₅ particles is present continuously on the charge separation promotion layer (i.e., in a form configuring a Ta₃N₅ layer), or may be present in a form of a plurality of Ta₃N₅ particles being non-continuously present on the charge separation promotion layer.

Relative to the total amount (100 mass %) of the material constituting the photocatalyst layer, the content of Ta₃N₅ is preferably greater than 70 mass % and not more than 100 mass %, more preferably greater than 90 mass % and not more than 100 mass %, even more preferably from 95 to 100 mass %, particularly preferably from 99 to 100 mass %, and most preferably 100 mass %.

The Ta₃N₅ may be doped with any material. Doping may be performed for the purpose of increasing the carrier density and improving the electrical conductivity of the photocatalyst layer (in this case, the band gap becomes narrower), but in the present invention, the Ta₃N₅ is preferably doped with a material in order to widen the band gap and promote separation of the holes and electrons rather than to improve the carrier density. When the Ta₃N₅ is doped with a material that widens the band gap, an advantage of further improving the photocurrent density of the oxygen generating electrode is obtained.

Examples of such a material that widens the bandgap include elements (dopants) such as Zr, Mg, Ba, and Na. Among these elements, the use of at least one of Zr and Mg is preferable from the perspective of shifting both the valence band and the conduction band of Ta₃N₅ upward to further improve the photocurrent density of the oxygen generating electrode.

The shape of the Ta₃N₅ is not particularly limited, and examples thereof include particulate, columnar, flat plate-shaped, and the like.

When the Ta₃N₅ is particulate-shaped, the average particle size of the primary particles of Ta₃N₅ is not particularly limited, but from the perspective of further improving the water splitting efficiency, the average particle size is preferably from 0.5 to 50 μm, more preferably from 0.5 to 10 μm, and even more preferably from 0.5 to 2 μm.

Here, the term “primary particle” refers to a particle of the smallest unit constituting the powder, and the average particle size is obtained by measuring the particle size (diameter) of any 100 Ta₃N₅ particles observed with a transmission electron microscope (TEM) or a scanning electron microscope (SEM), and then finding the arithmetic average thereof. Note that in a case where the particle shape is not a perfect circle, the longer diameter is measured. Also, in a case where the particle shape is indefinite (non-spherical), the diameter of a spherically approximated sphere is measured.

As the TEM, a device corresponding to the transmission electron microscope “JEM-2010 HC” (trade name, available from JEOL, Ltd.) can be used. In addition, as the SEM, a device corresponding to the ultra-high resolution electroemission scanning electron microscope “SU8010” (product name, available from Hitachi High-Technologies Corporation) can be used.

The thickness of the photocatalyst layer is not particularly limited, but the thickness is preferably from 0.01 to 3.0 μm, and more preferably from 0.5 to 2.0 μm from the perspective of achieving even better water splitting efficiency.

The photocatalyst layer may contain another photocatalyst besides the Ta₃N₅. Examples of other photocatalysts include oxides of Ta, oxynitrides of Ta (oxynitride compounds), oxynitrides of Ta and other metal elements, oxynitrides of Ti and other metal elements, and oxides of Nb and other metals.

Examples of oxynitrides of Ta and other metal elements include CaTaO₂N, SrTaO₂N, BaTaO₂N, and LaTaO₂N.

An example of an oxynitride of Ti and another metal element is LaTiO₂N.

Examples of oxynitrides of Nb and other metal elements include BaNbO₂N and SrNbO₂N.

The other photocatalyst may be doped with a dopant. Examples of dopants include elements such as Zr, Mg, W, Mo, Ni, Ca, La, Sr and Ba.

When another photocatalyst is included, the amount thereof is preferably 30 mass % or less, and more preferably 10 mass % or less with respect to the total amount (100 mass %) of the material constituting the photocatalyst layer.

### Current Collector Layer

The current collector layer has a role of causing electrons generated in the abovementioned Ta₃N₅ to flow. The charge separation promotion layer described below is formed on the current collector layer.

The shape of the current collector layer is not particularly limited, and may be, for example, a punching metal shape, a mesh shape, a lattice shape, or a porous body having penetrating pores.

The material constituting the current collector layer is not particularly limited as long as it is a material exhibiting electrically conductive properties, and examples thereof include carbon (C), a simple substance of metal, alloys, metal oxides, metal nitrides, and metal oxynitrides.

Specific examples of materials constituting the current collector layer include metals such as Au, Al, Cu, Cd, Co, Cr, Fe, Ga, Ge, Hg, Ir, In, Mn, Mo, Nb, Ni, Pb, Pd, Pt, Ru, Re, Rh, Sb, Sn, Zr, Ta, Ti, V, W, and Zn; and alloys thereof; oxides such as TiO₂, ZnO, SnO₂, Indium Tin Oxide (ITO), SnO, TiO₂ (: Nb), SrTiO₃ (: Nb), fluorine-doped tin oxide (FTO), CuAlO₂, CuGaO₂, CuInO₂, ZnO (: Al), ZnO (: Ga), and ZnO (: In); nitrides such as AlN, TiN and Ta₃N₅; oxynitrides such as TaON; and C.

Note that in the present specification, when α (: β) is described, a material having β doped in α is indicated. For example, TiO₂ (: Nb) indicates that Nb is doped in TiO₂.

Among these, from the perspective of further improving the photocurrent density of the oxygen generating electrode, the current collector layer preferably includes Ta, and more preferably has at least one layer containing Ta.

A substrate (hereinafter, also referred to as a “reinforcing substrate”) may be provided on the surface of the current collector layer of a side opposite the charge separation promotion layer to improve the mechanical strength of the oxygen generating electrode. In this case, if the current collector layer has a layer containing Ta, diffusion of components other than Ta (for example Ti described below) of the current collector layer can be suppressed, and the photocurrent density of the oxygen generating electrode is assumed to be further improved.

From the perspective of further exhibiting the abovementioned effect, the layer containing Ta is preferably laminated in contact with the charge separation promotion layer.

Here, the “layer containing Ta” refers to a layer containing Ta atoms in the greatest abundance of all of the atoms contained in this layer. Specifically, the content of Ta atoms in the layer containing Ta is preferably greater than 50 atm % and not greater than 100 atm %, more preferably from 70 to 100 atm %, and even more preferably from 90 to 100 atm %, relative to the total atoms (100 atm %) contained in this layer.

From the perspective of improving the rigidity of the current collector layer, the current collector layer preferably contains Ti, and more preferably has at least one layer containing Ti.

Here, the “layer containing Ti” refers to a layer containing Ti atoms in the greatest abundance of all of the atoms contained in this layer. Specifically, the content of Ti atoms in the layer containing Ti is preferably greater than 50 atm % and not greater than 100 atm %, more preferably from 70 to 100 atm %, and even more preferably from 90 to 100 atm %, relative to the total atoms (100 atm %) contained in this layer.

In particular, the current collector layer preferably includes both a layer containing Ta and a layer containing Ti in order to further improve the photocurrent density of the oxygen generating electrode while ensuring the rigidity of the current collector layer. In this case, from the perspective of further improving the photocurrent density of the oxygen generating electrode, the layer containing Ta is preferably disposed on the charge separation promotion layer side. More preferable is an aspect in which the layer containing Ta is in contact with the charge separation promotion layer, and the layer containing Ti is laminated on the surface of the layer containing Ta at a side opposite the surface that is in contact with the charge separation promotion layer.

The resistance value of the current collector layer is not particularly limited, but from the perspective of achieving even better characteristics (photocurrent density) of the oxygen generating electrode, the resistance value is preferably not greater than 10.0Ω/□, and more preferably not greater than 1.0Ω/□.

The resistance value of the current collector layer is measured by using a four-terminal four-probe method (Loresta GP MCP-T610 type available from Mitsubishi Chemical Analytech Co., Ltd., PSP probe) to measure the resistance value of a current collector layer formed on a glass substrate.

The thickness of the current collector layer is not particularly limited, but is preferably from 0.1 μm to 10 mm, and more preferably from 1 μm to 2 mm from the perspective of balancing the electrical conduction property and costs.

### Charge Separation Promotion Layer

The charge separation promotion layer functions to suppress recombination of carriers in the Ta₃N₅ as described above. The shape of the charge separation promotion layer is a continuous film, but is not particularly limited, and may be, for example, a film in which some non-continuous portions are present (discontinuous film), a punching metal shape, a mesh shape, a lattice shape, or a porous body having penetrating pores. In particular, in the case of sputtering, if the unevenness of the base is large, the charge separation promotion layer may become a discontinuous film.

From the perspective of causing the abovementioned function to be better exhibited, the charge separation promotion layer preferably includes an inorganic material in which an upper end of a valence band of the charge separation promotion layer is at a deeper level than an upper end of a valence band of the photocatalyst layer, and a lower end of a conduction band of the charge separation promotion layer is at a deeper level than a lower end of a conduction band of the photocatalyst layer. In the present specification, inorganic materials with such properties are also referred to as “specific inorganic materials”.

The charge separation promotion layer is disposed on the current collector layer. Specifically, the charge collector layer is disposed on one surface of the charge separation promotion layer, and the photocatalyst layer is disposed on a surface of the charge separation promotion layer of a side opposite the charge collector layer.

The specific inorganic material is preferably GaN. Since GaN is a nitride, an advantage is provided of being able to suppress the degradation of Ta₃N₅ in comparison to a case where an oxide formed in an oxygen atmosphere is used.

The specific inorganic material is preferably a crystalline inorganic material, and more preferably crystalline GaN. A crystalline inorganic material means an inorganic material with crystallinity, and crystalline GaN means GaN having crystallinity. Through the use of a specific inorganic material having crystallinity in this manner, the transport characteristics of the electrons in the charge separation promotion layer are improved, and the photocurrent density of the oxygen generating electrode is further improved.

In the present invention, “crystalline” refers to the property exhibited by a solid material having a spatially periodic atomic arrangement. For example, when the inorganic material is irradiated with X-rays, the inorganic material can be considered to have crystallinity if it is possible to confirm that a diffraction peak is obtained.

Specifically, the crystallinity of GaN can be determined by the presence or absence of a peak on the (002) surface of GaN measured by X-ray diffraction, but from the perspective of further increasing the degree of crystallization of GaN and further improving the photocurrent density of the oxygen generating electrode, the use of a crystalline GaN that exhibits the following diffraction peak intensity ratio is preferable.

That is, when the diffraction peak intensity of the (002) surface of the GaN layer produced by the following method A is regarded as 1, the diffraction peak intensity of the (002) surface of the crystalline GaN in the oxygen generating electrode of the present invention measured by X-ray diffraction using CuKα radiation is preferably 1 or greater, more preferably greater than 1, even more preferably 2 or greater, particularly preferably 3 or greater, and most preferably 4 or greater. Moreover, the upper limit value is not particularly limited.

Note that, in the present specification, the value of the diffraction peak intensity of the (002) surface of the crystalline GaN in the oxygen generating electrode, calculated based on the diffraction peak intensity of the (002) surface of the GaN layer produced by the method A, is abbreviated in some cases as the “diffraction peak intensity ratio”.

Method A: A GaN layer with a film thickness of 50 nm is formed on a sapphire substrate at 300° C. using plasma chemical vapor deposition.

The thickness of the charge separation promotion layer is not particularly limited, but is preferably from 10 to 100 nm, and more preferably from 30 to 70 nm from the perspective of better exhibiting the above-described function.

### Promoter

The oxygen generating electrode of the present invention may have a promoter. In this case, the promoter is supported by at least a portion of the Ta₃N₅. The promoter may be in a form of being present in a layered shape on the Ta₃N₅, or may be in a non-continuous form (e.g., in an island-like form, etc.) on the Ta₃N₅.

Examples of the promoter include metals such as Ti, Mn, Fe, Co, Ni, Cu, Ru, Rh, Pd, Ag, In, W, Ir, Mg, Ga, Ce, Cr and Pb, as well as metal compounds (including complex compounds), intermetallic compounds, alloys, oxides, complex oxides, nitrides, oxynitrides, sulfides, and oxysulfides of these.

Among these, from the perspective of excelling in oxygen generation promoter capacity, preferably at least one type selected from the group consisting of Ni, Fe, and Co is included, more preferably at least one type selected from the group consisting of Fe and Co is included, and even more preferably at least one type selected from the group consisting of oxides of Co (Co₃O₄ for example) and oxides of Fe (ferrihydrite (5Fe₂O₃.9H₂O) for example) is included.

For a case in which the promoter is formed in a layered manner, the thickness of the promoter is not particularly limited, but is preferably from 0.5 to 10 nm, and is more preferably from 0.5 to 2 nm.

### Other Layers

The oxygen generating electrode of the present invention may have other layers besides those described above. For example, a reinforcing substrate may be provided on the surface of the charge collector layer of a side opposite the charge separation promotion layer to improve the mechanical strength of the oxygen generating electrode. Additionally, an adhesive layer may be provided between the current collector layer and the reinforcing substrate.

Note that, for example, a metal plate (for example, Ta), an oxide substrate (for example, a quartz plate), a glass plate, a plastic sheet, or the like can be used as the reinforcing substrate.

### Method for Producing an Oxygen Generating Electrode

The method for producing the oxygen generating electrode of the present invention includes the steps of: forming a photocatalyst layer on a substrate; forming a charge separation promotion layer on the photocatalyst layer; forming a current collector layer on the charge separation promotion layer; and peeling the substrate from the photocatalyst layer.

The photocatalyst layer preferably contains at least one photocatalyst selected from the group consisting of, for example, Ta₃N₅ and other photocatalysts besides Ta₃N₅ (the other photocatalysts described above), and preferably contains Ta₃N₅.

In addition to an aspect in which the photocatalyst layer contains Ta₃N₅, the oxygen generating electrode obtained by the method for producing an oxygen generating electrode of the present invention also includes an aspect in which the photocatalyst layer contains a photocatalyst besides Ta₃N₅ and does not contain Ta₃N₅, but the aspect in which the photocatalyst layer contains Ta₃N₅ is preferable.

A preferable aspect of the oxygen generating electrode obtained by the method for producing an oxygen generating electrode according to the present invention is the same as the above-described oxygen generating electrode of the present invention, and thus descriptions thereof will be omitted.

The method for producing the oxygen generating electrode of the present invention will be described using, as an example, a production method that uses a particle transfer method illustrated in FIGS. 2 to 5 below.

FIGS. 2 to 5 are schematic views for explaining the steps for manufacturing the oxygen generating electrode of the present invention.

The production method illustrated in FIGS. 2 to 5 includes at least: a step S1 of forming a photocatalyst layer 12, a step S2 of forming a charge separation promotion layer 14 on one surface of the photocatalyst layer 12, and a step S3 of forming a current collector layer 16 on a surface of the charge separation promotion layer 14 of a side opposite the photocatalyst layer 12 side.

The method for producing an oxygen generating electrode of the present invention may further include performing a step S4 of removing non-contacting photocatalyst particles 18 after the abovementioned step S3. Further, with respect to step S4, as described below, it is preferable to have a reinforcing substrate forming step S4a or a washing step S4c.

Furthermore, the method for producing the oxygen generating electrode of the present invention may also include a step S5 of supporting a promoter after the abovementioned step S4. Note that support of the promoter is not limited to step S5. For example, instead of carrying out step S5, a photocatalyst made to support a promoter in advance may be used.

Furthermore, the method for producing an oxygen generating electrode of the present invention may also be provided with a metal wire adhesion step and an epoxy resin coating step. In this case, the metal wire adhesion step and the epoxy resin coating step are preferably performed before or after step S5.

### Step S1: Photocatalyst Layer Forming Step

As illustrated in FIG. 2, step S1 is a step of forming the photocatalyst layer 12 on a first substrate 20. The photocatalyst layer 12 includes photocatalyst particles 18.

As the first substrate 20, a material that is inactive in a reaction with a photocatalyst and has excellent chemical stability and heat resistance is preferably selected, and for example, a glass plate, a Ti plate, and a Cu plate are preferable, and a glass plate is more preferable.

Note that the surface of the first substrate 20 on which the photocatalyst layer 12 is disposed may be subjected to polishing and/or a washing treatment.

The method for forming the photocatalyst layer 12 is not particularly limited, and for example, may be a method of dispersing the photocatalyst particles 18 in a solvent to form a suspension, coating the suspension onto the first substrate 20, and then drying as necessary.

Examples of solvents in the suspension include water; alcohols such as methanol, ethanol, and 2-propanol; ketones such as acetone; aromatics such as benzene, toluene, and xylene; and the like. Note that when the photocatalyst particles 18 are dispersed in the solvent, the photocatalyst particles 18 can be uniformly dispersed in the solvent by implementing an ultrasonic treatment.

The method for coating the suspension onto the first substrate 20 is not particularly limited, and examples thereof include known methods such as drop casting, spraying, dipping, a squeegee method, a doctor blade method, spin coating, screen coating, roll coating, an ink jet method, and the like. In addition, a method may be used in which the first substrate 20 is disposed on a bottom surface of a container containing the suspension, the photocatalyst particles 18 are precipitated on the first substrate 20, and subsequently, the solvent is removed.

For the drying conditions after application, the temperature may be maintained at a temperature equal to or greater than the boiling point of the solvent, or may be held at or heated to around a temperature at which the solvent volatilizes in a short time (for example, approximately 15 to 200° C.).

The photocatalyst layer 12 is preferably free of other components such as a binder so that formation of a conductive path between the photocatalyst layer 12 and the charge separation promotion layer 14 is not inhibited. In particular, the photocatalyst layer 12 preferably does not contain a colored or insulating binder.

Note that in the example of FIG. 2, a method of laminating the photocatalyst particles 18 onto the first substrate 20 is illustrated as a method for forming the photocatalyst layer 12. However, for example, a method of forming a layer by kneading the photocatalyst particles 18 and a binder without using the first substrate 20, a method of forming a layer by pressurizing and molding the photocatalyst particles 18, and the like can also be used.

### Step S2: Charge Separation Promotion Layer Forming Step

As illustrated in FIG. 3, step S2 is a step of forming a charge separation promotion layer 14 on a surface of the photocatalyst layer 12 formed in step S1 on a side that is opposite the first substrate 20.

The method for forming the charge separation promotion layer 14 is preferably a vapor phase film formation method. The vapor phase film formation method is preferably a chemical vapor deposition method or a sputtering method, and a chemical vapor deposition method is more preferable. In particular, among chemical vapor deposition methods, plasma chemical vapor deposition is preferred because crystallization of the material constituting the charge separation promotion layer 14 is promoted at low temperatures by plasma.

From the perspective of improving the crystallinity of GaN, the substrate temperature of the first substrate 20 when forming the charge separation promotion layer 14 is preferably at least 300° C., more preferably at least 400° C., and even more preferably at least 500° C. Furthermore, from the perspective of reducing damage to the photocatalyst layer 12 while improving the crystallinity of GaN, the substrate temperature of the first substrate 20 when forming the charge separation promotion layer 14 is preferably 900° C. or lower, and more preferably 600° C. or lower.

In the example of FIG. 3, a case in which the charge separation promotion layer 14 is a continuous film is illustrated, but the present invention is not limited thereto, and for example, a film that is not a continuous film (for example, a film having a punching metal form, a mesh form, a lattice form, or a form of a porous body with penetrating pores) may be produced using various jigs. In this case, a jig having a form corresponding to the desired shape can be used as the jig, and, for example, in a case where a film in mesh form is to be produced, a jig in mesh form may be used.

### Step S3: Current Collector Layer Forming Step

As illustrated in FIG. 4, step S3 is a step of forming a current collector layer 16 on a surface of the charge separation promotion layer 14 of a side opposite the photocatalyst layer 12.

Examples of the method of forming the current collector layer 16 include a vapor deposition method and a sputtering method.

### Step S4: Non-Contacting Photocatalyst Particle Removal Step

Step S4 is a step of removing photocatalyst particles 18 that are not in contact with the charge separation promotion layer 14. The removal method is not particularly limited, and for example, a washing step S4c in which the photocatalyst particles 18 are removed through, inter alia, an ultrasonic washing treatment using a washing liquid can be applied.

Examples of the washing liquid include: water; an electrolyte aqueous solution; alcohols such as methanol and ethanol; aliphatic hydrocarbons such as pentane and hexane; aromatic hydrocarbons such as toluene and xylene; ketones such as acetone and methyl ethyl ketone; esters such as ethyl acetate; halides such as fluorocarbon; ethers such as diethyl ether and tetrahydrofuran; sulfoxides such as dimethyl sulfoxide; nitrogen-containing compounds such as dimethylformamide; and the like. Of these, water or a water-miscible solvent such as methanol, ethanol, or tetrahydrofuran is preferable.

When the mechanical strength of the current collector layer 16 is low and there is concern regarding breakage of the oxygen generating electrode in step S4, the current collector layer 16 is preferably subjected to a reinforcing substrate forming step S4a to provide a second substrate (not illustrated) on the surface of the current collector layer 16 on the side opposite the charge separation promotion layer 14 side, and is then supplied to the washing step S4c.

The method of providing the second substrate is not particularly limited, and examples thereof include a method of adhering the current collector layer 16 and the second substrate using an adhesive such as carbon tape.

Further, after passing through a substrate removal step S4b to remove the first substrate 20 as illustrated in FIG. 5 (preferably, after passing through the reinforcing substrate forming step S4a and then the substrate removal step S4b), the photocatalyst particles 18 that are not in contact with the charge separation promotion layer 14 are preferably removed by the washing step S4c.

As illustrated in FIG. 5, the substrate removal step S4b allows a portion of the photocatalyst particles 18 that are not in contact with the charge separation promotion layer 14 to be physically removed along with the first substrate 20. As a result, a laminate 100 formed by laminating the photocatalyst layer 12, the charge separation promotion layer 14, and the current collector layer 16 in this order is obtained. Note that the laminate 100 may be used as the oxygen generating electrode 10 as is, or may be subjected to each of the below-described steps.

On the other hand, the photocatalyst particles 18 that are in contact with the charge separation promotion layer 14 are physically bonded to the charge separation promotion layer 14 with a certain level of firmness, and therefore when the first substrate 20 is removed, the photocatalyst particles 18 remain on the charge separation promotion layer 14 side without falling off. In this case, the non-contacting photocatalyst particles 18 that are not removed in the substrate removal step S4b are preferably further subjected to a removal treatment by the washing step S4c.

The method of removing the first substrate 20 performed in the substrate removal step S4b is not particularly limited, and examples include a method of mechanically removing the first substrate 20, a method of wetting a laminated portion of the photocatalyst particles 18 by immersion in water to weaken the bonding between photocatalyst particles 18 and then removing the first substrate 20, a method of dissolving and removing the first substrate 20 using an acid, alkali, or other chemical agent, and a method of physically destroying and removing the first substrate 20, but a method of mechanically removing the first substrate 20 is preferable because the potential for damaging the photocatalyst layer 12 is low.

### Step S5: Promoter Support Step

The method for manufacturing the oxygen generating electrode 10 may include a promoter support step (step S5) of supporting a promoter on the photocatalyst layer 12.

The method for supporting the promoter is not particularly limited, and a general method such as impregnation, electrodeposition, sputtering, and vapor deposition can be used. The electrodeposition method may be a photoelectric deposition method in which light irradiation is performed during electrodeposition.

Note that the promoter support step may be repeated two or more times.

### Other Steps

The method for producing the oxygen generating electrode of the present invention may include a metal wire adhesion step and an epoxy resin coating step. These steps can be performed before or after step S5.

The metal wire adhesion step is a step of adhering a metal wire to the laminate 100, and for example, the metal wire can be soldered using metallic indium. A metal wire with a resin coating may be used as the metal wire.

The epoxy resin coating step is a step of coating a surface of the laminate 100 other than the photocatalyst layer 12 with an epoxy resin in order to suppress leakage from the exposed metal portion. As the epoxy resin, a known epoxy resin can be used.

### Method for Producing Other Oxygen Generating Electrodes

The method for producing the above-described oxygen generating electrode was described by presenting a method that uses a particle transfer method as an example. However, the oxygen generating electrode of the present invention may be produced by a method besides the above-described method, provided that the function of the charge separation layer of the resulting oxygen generating electrode is exhibited.

Examples of methods for producing the oxygen generating electrode besides the above-described method include a vapor phase film formation method and the like. An example of a production method that uses the vapor phase film formation method without using the particle transfer method is provided below as a method for producing the oxygen generating electrode of the present invention.

First, a current collector layer is formed on the reinforcing substrate. Next, a GaN film is formed as a charge separation layer on the charge collector layer using a metal organic chemical vapor deposition method (MOCVD). Next, an oxygen generating electrode is obtained by forming a film of Ta metal on the charge separation layer using a sputtering method, a vapor deposition method, or the like, and then nitriding under an ammonia flow to form Ta₃N₅ (a photocatalyst layer). Note that the manufacturing method may include a step of supporting a promoter.

For information on the method for producing the photocatalyst layer (Ta₃N₅) or the like using a vapor phase film formation method, the method disclosed, for example, in “Angew. Chem. Int. Ed. 2017, 56, 4739-4743” can also be referenced.

In the method for producing an oxygen generating electrode using the vapor phase film formation method described above, when a metal is used as the material for the reinforcing substrate, Ta is preferable as the metal. In this case, Ta provides an advantage of suppressing impurity diffusion from the reinforcing substrate during high-temperature treatment in the subsequent nitriding process.

In addition, when glass or oxide is used as the reinforcing substrate, selecting Ta as the material of the current collector layer results the same effect as when using Ta as the material of the reinforcing substrate.

In addition, when glass or an oxide is used as the material of the reinforcing substrate, using a transparent conductive film as the material of the current collector layer allows the production of the photocatalyst layer (Ta₃N₅) via a transparent current collector layer on the transparent reinforcing substrate. Examples of the transparent conductive film include oxides and nitrides, but nitrides are preferable when considering nitriding resistance. In this case, even if light is incident from the back surface (the surface of the reinforcing substrate of the side opposite the surface on which the current collector layer is formed), the photocatalyst electrode functions, and therefore the light usage efficiency can be increased by disposing the transparent conductive film in tandem with the plurality of electrodes.

For a case in which a current collector layer is formed on an insulating reinforcing substrate other than a metal substrate, and the Ta₃N₅ layer (photocatalyst layer) is produced by subjecting the Ta film to a nitriding treatment, when GaN is provided as a charge separation layer between the current collector layer and the Ta film, an advantage of the function of the current collector layer not being lost is obtained because the GaN prevents nitriding of the current collector layer.

### Module

The module of the present invention has the oxygen generating electrode described above.

The module is provided with, for example, a cell in which water is stored, an oxygen generating electrode and a photocatalyst electrode for generating hydrogen (hereinafter, referred to as a “hydrogen generating electrode”), which are disposed so as to be immersed in water in the cell, and a voltage applying means connected to the oxygen generating electrode and the hydrogen generating electrode to apply a voltage using the oxygen generating electrode as an anode and the hydrogen generating electrode as a cathode. The module of the present invention is suitably used as a photocatalyst module for water splitting.

When the oxygen generating electrode is irradiated with light, the splitting of water proceeds, oxygen is generated on the surface of the oxygen generating electrode, and hydrogen is generated on the surface of the hydrogen generating electrode.

The light to be irradiated may be any light that can cause a photodegradation reaction, and specifically, sunlight and other such visible light, ultraviolet light, infrared light, and the like can be used, and among these, sunlight, which is available in an inexhaustible supply, is preferable.

### EXAMPLES

The oxygen generating electrode of the present invention will be described in detail below using examples. However, the present invention is not limited thereto.

### Example 1

Synthesis of Ta₃N₅ Particles

Ta₃N₅ particles were obtained by treating Ta₂O₅ (available from Kojundo Chemical Laboratory Co., Ltd.) in a vertical type tubular furnace at 850° C. for 15 hours in an ammonia gas stream.

Production of a Ta₃N₅ Layer

A suspension in which 50 mg of Ta₃N₅ particles were suspended in 1 mL of 2-propanol was prepared using ultrasonic waves, the suspension was drop cast onto a glass substrate (size: 10×30 mm), and the 2-propanol in the suspension was volatilized to thereby obtain a Ta₃N₅ particle film (Ta₃N₅ layer) in which Ta₃N₅ particles were deposited in a film form on a glass substrate.

### Film Formation of a GaN Layer

With the use of trimethylgallium (TMG) as a Ga source, plasma chemical vapor deposition (plasma CVD) was used to form a GaN layer, while reacting with a nitrogen plasma, on the surface of the glass substrate on which the Ta₃N₅ layer was deposited. At this time, the substrate temperature of the glass substrate was set to 500° C., and the film thickness was approximately 50 nm (film formation time of 5 minutes).

### Film Formation of a Current Collector Layer (Ta Layer and Ti Layer)

A Ta layer (film thickness of 50 nm) was formed by an RF (high frequency) magnetron sputtering film formation method at 100 W and 350° C., after which a Ti layer (film thickness 5 μm) was formed at 200 W and 200° C., and a laminate A of glass substrate/Ta₃N₅/GaN/Ta/Ti was prepared. The glass substrate was peeled from the laminate A and excess Ta₃N₅ particles were removed through an ultrasound treatment in water to create a Ta₃N₅/GaN/Ta/Ti laminate B which was ready for use as an electrode.

### Promoter Support

The laminate B was immersed in an aqueous solution of 0.05 M iron nitrate and 0.375 M sodium nitrate, and then removed therefrom and heated for 8 minutes at 100° C. to cause ferrihydrite (5Fe₂O₃.9H₂O) to be supported on the surface of the laminate B.

A solution was then prepared by adding 0.35 mL of a 28% ammonia aqueous solution dropwise to a 0.04 M cobalt acetate ethanol solution. After being made to support the ferrihydrite, the laminate B was immersed in this solution, and the solution was subjected to a solvothermal treatment for 1 hour at 120° C. in a Teflon® sealed hydrothermal container to thereby cause Co₃O₄, which is a promoter, to be supported on the ferrihydrite surface.

In this manner, the promoter Co₃O₄ and ferrihydrite, the Ta₃N₅ layer serving as the photocatalyst layer, the GaN layer serving as the charge separation promotion layer, and the Ta layer and the Ti layer serving as the charge collector layers were laminated in this order, and an oxygen generating electrode of Example 1 (Co₃O₄/5Fe₂O₃.9H₂O/Ta₃N₅/GaN/Ta/Ti) was obtained.

### Example 2

An oxygen generating electrode (Co₃O₄/5Fe₂O₃.9H₂O/Ta₃N₅/GaN/Zr/Ti) of Example 2 was obtained in the same manner as in Example 1 with the exception that a Zr layer was produced in place of the Ta layer in the “<Film Formation of a Current Collector Layer (Ta Layer and Ti Layer)>” of Example 1.

### Example 3

An oxygen generating electrode (Co₃O₄/5Fe₂O₃.9H₂O/Ta₃N₅/GaN/Sn/Ti) of Example 3 was obtained in the same manner as in Example 1 with the exception that a Sn layer was produced in place of the Ta layer in the “<Film Formation of a Current Collector Layer (Ta Layer and Ti Layer)>” of Example 1.

### Example 4

An oxygen generating electrode (Co₃O₄/5Fe₂O₃.9H₂O/Ta₃N₅/GaN/Ta/Ti) of Example 4 was obtained in the same manner as in Example 1 with the exception that the substrate temperature was changed to 600° C. in the “<Film Formation of a GaN Layer>” of Example 1.

### Example 5

An oxygen generating electrode (Co₃O₄/5Fe₂O₃.9H₂O/Ta₃N₅/GaN/Ta/Ti) of Example 5 was obtained in the same manner as in Example 1 with the exception that the substrate temperature was changed to 400° C. in the “<Film Formation of a GaN Layer>” of Example 1.

### Example 6

An oxygen generating electrode (Co_{304/5}Fe₂O₃.9H₂O/Ta₃N₅/GaN/Ta/Ti) of Example 6 was obtained in the same manner as in Example 1 with the exception that the substrate temperature was changed to 300° C. in the “<Film Formation of a GaN Layer>” of Example 1.

### Example 7

An oxygen generating electrode (Co₃O₄/5Fe₂O₃.9H₂O/Ta₃N₅: Zr, Mg/GaN/Ta/Ti) of Example 7 was obtained in the same manner as in Example 1 with the exception that the “<Synthesis of Ta₃N₅ Particles>” of Example 1 was changed in the following manner. Note that “Ta₃N₅: Zr, Mg” indicates that Ta₃N₅ is doped with Zr and Mg.

The method for synthesizing the Ta₃N₅: Zr, Mg particles is presented. First, a mixture was prepared by mixing ZrO(NO₃)₂.2H₂O and Mg(NO₃)₂.6H₂O in Ta₂O₅ (available from Kojundo Chemical Laboratory Co., Ltd.), and the mixture was calcined in the atmosphere to obtain Ta₂O₃: Mg, Zr particles. Note that a portion of the Ta was replaced with Zr and Mg such that 25% of Ta is replaced with Zr and Mg (the ratio of Zr:Mg=2:1).

The particles were treated in a vertical type tubular furnace at 850° C. for 15 hours under an ammonia gas stream, and Ta₃N₅: Mg, Zr particles were obtained.

### Comparative Example 1

An oxygen generating electrode (Co₃O₄/5Fe₂O₃.9H₂O/Ta₃N₅/Ta/Ti) of Comparative Example 1 was obtained in the same manner as in Example 1 with the exception that the “<Film Formation of a GaN Layer>” of Example 1 was not implemented.

### Comparative Example 2

An oxygen generating electrode (Co₃O₄/5Fe₂O₃.9H₂O/Ta₃N₅: Zr, Mg/Ta/Ti) of Comparative Example 2 was obtained in the same manner as in Example 7 with the exception that the <Film Formation of a GaN Layer>” of Example 7 was not implemented.

### Comparative Example 3

An oxygen generating electrode (Co₃O₄/5Fe₂O₃.9H₂O/TiO₂; Rh, Sb/Sn/Ti) of Comparative Example 3 was obtained in the same manner as in Example 3 with the exception that TiO₂; Rh, Sb particles were used in place of the Ta₃N₅ particles, and the “<Film Formation of a GaN Layer>” of Example 3 was not implemented. Note that “TiO₂; Rh, Sb” indicates that the TiO₂ was doped with Rh and Sb.

The method for synthesizing the TiO₂; Rh, Sb particles is presented. First, titanium oxide (available from Kojundo Chemical Laboratory Co., Ltd.), rhodium oxide (available from Wako Pure Chemical Industries, Ltd.), and antimony oxide (available from Nacalai Tesque Inc.) were mixed with an agate mortar to obtain a mixture. Each of the components was blended at an amount such that Ti/Rh/Sb=0.961/0.013/0.026 in terms of the atomic ratio. The obtained mixture was placed in an electric furnace and calcined for 1 hour at 900° C. in the atmosphere, crushed, and once again calcined in an electric furnace at 1150° C. for 10 hours in the atmosphere. In this manner, TiO₂; Rh, Sb particles were obtained.

### Comparative Example 4

An oxygen generating electrode (Co₃O₄/5Fe₂O₃.9H₂O/SnNb₂O₆/Sn/Ti) of Comparative Example 4 was obtained in the same manner as in Example 3 with the exception that SnNb₂O₆ particles were used in place of the Ta₃N₅ particles, and the “<Film Formation of a GaN Layer>” of Example 3 was not implemented.

The method for synthesizing the SnNb₂O₆ particles is presented. First, tin(II) oxide (available from Wako Pure Chemical Industries, Ltd.) and niobium oxide (available from Sigma-Aldrich Japan LLC) were mixed with agate mortar to obtain a mixture. Each of the components was blended at an amount such that Sn/Nb=½ in terms of the atomic ratio. Next, the obtained mixture was placed in an electrical tubular furnace and subjected to an annealing treatment at 800° C. for 10 hours under a nitrogen flow, and thereby SnNb₂O₆ particles were obtained.

### Comparative Example 5

An oxygen generating electrode (Co₃O₄/5Fe₂O₃.9H₂O/BaTaO₂N/Sn/Ti) of Comparative Example 5 was obtained in the same manner as in Example 3 with the exception that BaTaO₂N particles were used in place of the Ta₃N₅ particles, and the “<Film Formation of a GaN Layer>” of Example 3 was not implemented.

The method for synthesizing the BaTaO₂N particles is presented. First, tantalum oxide (available from Kojundo Chemical Laboratory Co., Ltd.) and barium carbonate (available from Kanto Chemical Co., Inc.) were mixed with an agate mortar to obtain a mixture. Each of the components was blended at an amount such that Ta/Ba=1/1 in terms of an atomic ratio. Next, the obtained mixture was placed in an electric furnace and calcined for 10 hours at 1000° C., and an oxide precursor was obtained. The oxide precursor was placed in an electric tubular furnace and subjected to a nitriding treatment at 900° C. for 10 hours under a 100% ammonia gas stream, and BaTaO₂N particles were obtained.

### Comparative Example 6

An oxygen generating electrode (Co₃O₄/5Fe₂O₃.9H₂O/BiVO₄/Sn/Ti) of Comparative Example 6 was obtained in the same manner as in Example 3 with the exception that BiVO₄ particles were used in place of the Ta₃N₅ particles, and the “<Film Formation of a GaN Layer>” of Example 3 was not implemented.

The method for synthesizing the BiVO₄ particles is presented. First, a nitric acid aqueous solution of NH₄VO₃ (available from Kanto Chemical Co., Inc.) and a nitric acid aqueous solution of Bi(NO₃)₃.5H₂O (available from Kanto Chemical Co., Inc.) were prepared and respectively stirred for 30 minutes, after which the two types of solutions were mixed at a molar ratio of 1:1, and a mixed solution was obtained. Next, urea (available from Kanto Chemical Co., Inc.) was added to the mixed solution, after which the mixed solution was sealed in an autoclave and subjected to a microwave hydrothermal reaction for 1 hour at 200° C., and BiVO₄ particles were obtained.

### Evaluation Test

In the following evaluations, products obtained by adhering metal wires to each of the oxygen generating electrodes of the examples and comparative examples were used. Adhesion of the metal wires was performed by soldering with metallic indium.

### Photocurrent Density

The photocurrent density of each of the oxygen generating electrodes of the examples and comparative examples was evaluated through current-potential measurements with a three-electrode system using a potentiostat (available from Hokuto Denko Corporation, product name “HSV-110”). A separable flask with a planar window was used in an electrochemical cell, an Ag/AgCl electrode was used as the reference electrode, and a Pt wire was used as the counter electrode. As the electrolyte, 0.2 M of K₂HPO₄+KOH (pH=13) was used. The inside of the electrochemical cell was filled with argon, and dissolved oxygen and carbon dioxide were removed by sufficiently bubbling prior to measurements. A solar simulator (available from San-Ei Electric Co., Ltd., product name “XES-40S2-CE”, AM1.5G) was used as a light source in the electrochemical measurements.

Furthermore, the photocurrent density (mA/cm²) at 1.23 V (vs. RHE) was measured for each of the oxygen generating electrodes produced in the examples and comparative examples. Note that RHE is an abbreviation for reversible hydrogen electrode. The evaluation criteria were as follows, and the evaluation results are shown in Table 1.

◯: Photocurrent density was 3.5 mA/cm² or greater.

X: Photocurrent density was less than 3.5 mA/cm².

### Peak Intensity of the GaN Layer

A GaN layer with a film thickness of 50 nm was formed on a sapphire substrate at 300° C. using a plasma chemical vapor deposition method and the reference sample A was obtained.

The diffraction peak intensity of the (002) surface of the GaN layer of the reference sample A was measured under the following conditions using an X-ray diffraction apparatus (product name “SmartLab”, available from Rigaku Corporation).

Next, under the same measurement conditions as the reference sample A, the diffraction peak intensity of the (002) surface of the GaN layer of each of the oxygen generating electrodes of Examples 1 and 4 to 6 was measured.

The value of the diffraction peak intensity (peak intensity ratio) of the (002) surface of the GaN layer of each of the Examples 3 to 6 was calculated regarding the diffraction peak intensity of the (002) surface of the GaN layer of the reference sample A as 1. The results are shown in Table 1.

### Measurement Conditions

Radiation source: CuKα radiation

Measurement range of 2θ: 30 to 40 degrees

Scan speed: 1 deg/min

Sampling interval: 0.01 degrees

### Evaluation Results

The results of the abovementioned evaluation test are shown in Table 1.

TABLE 1

| | | | Substrate | | Evaluation Results | | |
|---|---|---|---|---|---|---|---|
| | | | Temperature | | | | Diffraction |
| | | | When Forming | Current | Current Density | | Peak |
| | | GaN | GaN Layer | Collector | Value | | Intensity |
| | Photocatalyst | Layer | (° C.) | Layer | (mA/ cm²) | Evaluation | Ratio |
| Example 1 | Ta₃N₅ | Yes | 500 | Ta/Ti | 4.2 | ◯ | 4.2 |
| Example 2 | Ta₃N₅ | Yes | 500 | Zr/Ti | 3.6 | ◯ | — |
| Example 3 | Ta₃N₅ | Yes | 500 | Sn/Ti | 3.7 | ◯ | — |
| Example 4 | Ta₃N₅ | Yes | 600 | Ta/Ti | 4.1 | ◯ | 2.1 |
| Example 5 | Ta₃N₅ | Yes | 400 | Ta/Ti | 3.8 | ◯ | 2.0 |
| Example 6 | Ta₃N₅ | Yes | 300 | Ta/Ti | 3.5 | ◯ | 1.0 |
| Example 7 | Ta₃N₅: Zr, Mg | Yes | 500 | Ta/Ti | 4.5 | ◯ | — |
| Comparative Example 1 | Ta₃N₅ | No | — | Ta/Ti | 3.0 | X | — |
| Comparative Example 2 | Ta₃N₅: Zr, Mg | No | — | Ta/Ti | 3.1 | X | — |
| Comparative Example 3 | TiO₂: Rh, Sb | No | — | Sn/Ti | 0.15 | X | — |
| Comparative Example 4 | SnNb₂O₆ | No | — | Sn/Ti | 0.06 | X | — |
| Comparative Example 5 | BaTaO₂N | No | — | Sn/Ti | 1.1 | X | — |
| Comparative Example 6 | BiVO₄ | No | — | Sn/Ti | 1.7 | X | — |

As indicated by the evaluation results in Table 1, all of the oxygen generating electrodes of the examples exhibited excellent photocurrent density.

According to a comparison of Examples 1 and 4 to 6, when the peak intensity ratio exceeded 1 (preferably 2 or greater) (Examples 1, 4 and 5), the photocurrent density was further improved. From this, it is hypothesized that when the substrate temperature upon forming the GaN layer is higher than 300° C. (preferably 400° C. or higher), the degree of crystallinity of the GaN layer is further improved, and an oxygen generating electrode with even more excellent photocurrent density is obtained.

A comparison of Examples 1 to 3 showed that by providing the current collector layer with a Ta layer (Example 1), an oxygen generating electrode with even better photocurrent density can be obtained.

A comparison of Examples 1 and 7 showed that an oxygen generating electrode with even better photocurrent density can be obtained when Ta₃N₅ is doped with at least one element of Zr and Mg (Example 7).

On the other hand, none of the oxygen generating electrodes of the comparative examples had a GaN layer, and therefore a deterioration in photocurrent density was exhibited.

### EXPLANATION OF REFERENCES

10 Oxygen generating electrode
12 Photocatalyst layer
14 Charge separation promotion layer
16 Current collector layer
18 Photocatalyst particles
20 First substrate
100 Laminate

What is claimed is:

1. A photocatalyst electrode for oxygen generation comprising a current collector layer and a photocatalyst layer containing Ta₃N₅,
wherein the photocatalyst electrode for oxygen generation has a charge separation promotion layer between the current collector layer and the photocatalyst layer,
the charge separation promotion layer comprises an inorganic material in which an upper end of a valence band of the charge separation promotion layer is at a deeper level than an upper end of a valence band of the photocatalyst layer, and a lower end of a conduction band of the charge separation promotion layer is at a deeper level than a lower end of a conduction band of the photocatalyst layer, and
the inorganic material is GaN.

2. The photocatalyst electrode for oxygen generation according to claim 1, wherein the inorganic material is a crystalline inorganic material.

3. The photocatalyst electrode for oxygen generation according to claim 2, wherein the inorganic material is crystalline GaN.

4. The photocatalyst electrode for oxygen generation according to claim 3, wherein a diffraction peak intensity of a (002) surface of the crystalline GaN measured by X-ray diffraction using CuKα radiation is greater than 1 when the diffraction peak intensity of the (002) surface of a GaN layer produced by method A is regarded as 1;
Method A: A GaN layer with a film thickness of 50 nm is formed on a sapphire substrate at 300° C. using plasma chemical vapor deposition method.

5. The photocatalyst electrode for oxygen generation according to claim 1, wherein the Ta₃N₅ is Ta₃N₅ doped with a material that widens the bandgap.

6. The photocatalyst electrode for oxygen generation according to claim 5, wherein the material that widens the bandgap is at least one element of Zr and Mg.

7. The photocatalyst electrode for oxygen generation according to claim 1, wherein the current collector layer comprises at least one layer containing Ta.

8. The photocatalyst electrode for oxygen generation according to claim 1, wherein the current collector layer comprises at least one layer containing Ti.

9. The photocatalyst electrode for oxygen generation according to claim 7, wherein the layer containing Ta is laminated in contact with the charge separation promotion layer.

10. The photocatalyst electrode for oxygen generation according to claim 9, wherein the current collector layer comprises at least one layer containing Ti; and
the layer containing Ti is laminated on a surface of the layer containing the Ta, the surface being of a side opposite the surface in contact with the charge separation promotion layer.

11. A module comprising the photocatalyst electrode for oxygen generation according to claim 1.

12. A method for producing a photocatalyst electrode for oxygen generation, the method comprising the steps of:
forming a photocatalyst layer containing Ta₃N₅ on a substrate;
forming a charge separation promotion layer on the photocatalyst layer;
forming a current collector layer on the charge separation promotion layer; and
peeling the substrate from the photocatalyst layer,
wherein the charge separation promotion layer comprises an inorganic material in which an upper end of a valence band of the charge separation promotion layer is at a deeper level than an upper end of a valence band of the photocatalyst layer, and a lower end of a conduction band of the charge separation promotion layer is at a deeper level than a lower end of a conduction band of the photocatalyst layer, and
the inorganic material is GaN.

13. The method for producing a photocatalyst electrode for oxygen generation according to claim 12, wherein the inorganic material is a crystalline inorganic material.

14. The method for producing a photocatalyst electrode for oxygen generation according to claim 13, wherein the inorganic material is crystalline GaN.

15. The method for producing a photocatalyst electrode for oxygen generation according to claim 14, wherein a diffraction peak intensity of a (002) surface of the crystalline GaN measured by X-ray diffraction using CuKα radiation is greater than 1 when the diffraction peak intensity of the (002) surface of a GaN layer produced by method A is regarded as 1;
Method A: A GaN layer with a film thickness of 50 nm is formed on a sapphire substrate at 300° C. using plasma chemical vapor deposition.

16. The method for producing a photocatalyst electrode for oxygen generation according to claim 12, wherein the charge separation promotion layer is formed by a vapor phase film formation method.

17. The method for producing a photocatalyst electrode for oxygen generation according to claim 16, wherein the vapor phase film formation method is a chemical vapor deposition method or sputtering method.

18. The method for producing a photocatalyst electrode for oxygen generation according to claim 17, wherein the chemical vapor deposition method is a plasma chemical vapor deposition method.

19. The photocatalyst electrode for oxygen generation according to claim 2, wherein the Ta₃N₅ is Ta₃N₅ doped with a material that widens the bandgap.

20. The photocatalyst electrode for oxygen generation according to claim 3, wherein the Ta₃N₅ is Ta₃N₅ doped with a material that widens the bandgap.
